(19) United States
(12) Patent Application Publication
(10) Pub. No.: US 2004/0011464 A1
(43) Pub. Date: Jan. 22, 2004

(54) Promotion of independence between degree of dissociation of reactive gas and the amount of ionization of dilutant gas via diverse gas injection

(75) Inventor: Hongqing Shan, Cupertino, CA (US)

Correspondence Address: PATENT COUNSEL, APPLIED MATERIALS, INC., Legal Affairs Department, P.O. BOX 450 A, Santa Clara, CA, 95052, US

(73) Assignee: Applied Materials, Inc.

(21) Appl. No.: 10/198,268

(22) Filed: Jul. 16, 2002

(51) Int. Cl. H01L 21/302

(52) U.S. Cl. 156/345.38; 438/711

(57) ABSTRACT

A plasma processing chamber and method provides the ability to make dissociation of reactive gasses independent from ionization of dilutant gasses. It also provides the ability to control the amount of dissociation of reactive gasses. The distance between the injection points for the reactive gasses and the dilutant gasses is substantially larger than the distance between the wafer pedestal and where the reactive gasses are injected. This distance between injection locations helps makes dissociation of reactive gasses independent from ionization of dilutant gasses. The use of a secondary excitation source that excites substantially only the dilutant gasses further contributes to the ability to control dissociation of reactive gasses independently of ionization of dilutant gasses. The ability to adjust the location of the injection point of the reactive gasses further provides the ability to control dissociation in a novel way. The degree of dissociation may be controlled according to specific process requirements.

### BACKGROUND OF THE INVENTION

The present invention relates to the field of processing semiconductor wafers. More specifically, the present invention relates to control of dissociation and ionization of constituent processing gasses used to process a semiconductor wafer in a plasma processing chamber.

Plasma processing is very important to a number of the world's large manufacturing industries. In particular, plasma etch processing is essential to the manufacture of semiconductors, integrated circuits, and microelectronic devices. These products are used in many industries, including the electronics, biomedical, computer, and aerospace industries.

Plasma etching is useful to modify the surface properties of a workpiece. For example, in semiconductor fabrication the workpiece is a semiconductor wafer and plasma etching removes patterned material from the surface of the wafer. Etch process requirements may vary between wafers depending on, for example, the target depth of holes that need to be etched into the surface of the wafer, or the particular type of material layer being etched. Thus, a wafer having one pattern usually has different etch requirements than another wafer having another pattern.

These differing etch requirements dictate that such processing parameters as process gas chemistry, temperature, pressure, gas flow rates, and applied power also differ between etch process recipes. Typically, these processing parameters for each etch process recipe are quite precise. That is because each etch process has a narrow process window. The window is often so narrow for a given process, at least in part, because there is a functional linkage between the degree of ionization of the dilutant gasses and the degree of dissociation of the reactive gasses. While it is often desirable to maintain a high level of excitation power to ensure plenty of ionization of the dilutant gas (this helps to obtain verticality of walls and etch depth of features), this competes with the concern that excessive excitation energy may cause excessive dissociation of the reactive gas resulting in an overabundance of free radicals in the plasma.

The development of inductively coupled plasma (ICP) reactors and capacitively coupled plasma (CCP) reactors provides some diversity in how energy is coupled into a plasma for processing. The common elements of the two types of plasma reactors include a reactor chamber and a workpiece support within the chamber. The workpiece is placed on the support and a process gas is introduced into the chamber. Plasma is ignited and sustained within the reactor chamber by subjecting the process gas to an energy emission.

This energy emission breaks down or dissociates the process gas into several chemically reactive species. Some of these species are ionized, giving them a net electric charge, which renders them maneuverable in the chamber by an electric field from a bias signal applied to the workpiece. This maneuverability allows, for example, a nearly perfect vertical etch on the workpiece by having the fragments impact the surface of the workpiece at an angle perpendicular to the surface.

An ICP reactor is typically employed when a high etch rate plasma is desired, because the ICP reactor generally has a higher ion density that results in a higher etch rate. However, etch selectivity is often degraded at higher etch rates. Thus, although an ICP reactor tends to have higher plasma density and higher etch rates, the etch selectivity tends to be better in a capacitively coupled reactor. Conversely, a CCP reactor usually has a better etch selectivity than an ICP reactor, but has plasma density and etch rate characteristics that tend to be inferior to an ICP reactor.

One reason for the difference in etch selectivity between inductively coupled and capacitively coupled reactors is the amount of dissociation of the process gasses within the plasma. The plasma of an ICP reactor typically has more dissociation than a CCP reactor. Dissociation means that the molecules of the process gas are separated into two or more of the constituent parts of the molecules, generally as a result of inelastic collisions with electrons.

These constituent parts, or species, formed as a result of the dissociation, may contain atoms, ions, and radicals. Depending on several processing parameters (e.g., the chemistry of the process gas, the source power, the chamber pressure), the species formed may be a bigger species or a smaller species. Less-dissociated species tend to be bigger. More highly dissociated species tend to be smaller.

Thus, the plasma in an ICP reactor tends to dissociate into relatively small species (compared to a CCP reactor) because an ICP reactor typically has more dissociation. Importantly, these small species can have an adverse effect on selectivity. For example, free ionic fluorine (F*) is a small species that is usually undesirable because it tends to etch most any material and, thus, degrades etch selectivity.

In contrast, the plasma in a CCP reactor tends to dissociate into relatively bigger species (compared to an ICP reactor). This difference in relative proportion of species sizes between CCP reactors and ICP reactors explains, at least in part, why etch selectivity is usually better in a CCP reactor than in an ICP reactor.

For example, in an ICP reactor with a process gas of CHF₃, the irradiated process gas dissociates into several species including C, CH, F, C₂, CHF, CF₂, and CHF₂. The bigger, or less-dissociated, species include CHF, CF₂ and CHF₂, which tend to more resemble the molecular structure of the process gas. The smaller, or highly-dissociated, species include C, F, CH, CF, and C₂, which tend to more resemble the atomic constituents of the gas.

Empirical observation bears out that when an inductively coupled plasma reactor is used to excite a fluorocarbon process gas such as CF₄, C₂F₆, or C₄F₈, the consistent result is that they all dissociate so that CF* is usually the dominant species. Although the amounts of free F* and other species do tend to vary somewhat, the ratio of the bigger species to smaller species changes very little.

An excess of free radicals as a result of excess dissociations of the reactive gas constituents is problematic. The excess free radicals cause undesired reactions and byproducts.

In plasma etch, oxide etch in particular, photoresist selectivity is a vital parameter since etch is preferential micro-machining enabled by the presence of the photoresist on top of the film to be etched. More dissociation of gasses injected into the chamber means more free radicals that can etch photoresist faster. As a consequence, integrity of the patterns to be fabricated is jeopardized.

Similarly, an excessive degree of dissociation can reduce underlayer selectivity. This is so because there normally exists more than one film layer underneath the resist, and one has to etch one underlayer with selectivity to another. When such an underlayer is a dielectric film, it can be easily etched away by free radicals generated by high degree of plasma dissociation. In oxide etch, it is the free F* that etches away such films as resist and nitride faster than oxide.

Thus, what is needed is a method and apparatus for actively controlling the density of the bigger species and the smaller species generated within the plasma so that the ratio of the two can be increased or decreased. Of, course, the atomic composition of the process gas will limit the species that can be generated, but controlling densities of each species would affect the ratio. Increasing the ratio would tend to give better etch selectivity and decreasing the ratio would give better etch stop depth.

A number of approaches for controlling the relative density of species generated within the plasma have been tried in an attempt to broaden the process window, but with only limited success. Changing the chemistry of the process gas has yielded incremental success, however there have been no significant breakthroughs. Adjusting other processing parameters, such as the source power, bias power, and bias frequency have shifted operating points, however these adjustments have not drastically broadened the process window.

One promising technique is to pulse or time-modulate the plasma. Although this has been demonstrated to give some control of relative constituent density, it runs the risk of reducing the amount of ionization that is so useful for micro-machining deep holes with vertical walls.

Accordingly, what is needed is a method and an apparatus for actively controlling the species generated within a plasma, without adversely affecting the amount of ionization that is occurring in the plasma. Stated another way, what is needed is a mechanism for making dissociation of reactive gasses independent from ionization of dilutant gasses. In plasma processing, dissociation control is an important parameter. The degrees to which the reactive gasses are dissociated affects not only etch rate, but also profile and selectivity. Gasses injected into an evacuated chamber are dissociated and ionized via plasma inside the chamber. Normally, it is a plasma source and its recipe that controls dissociation and ionization.

Moreover, it is desirable that the method and apparatus have a high plasma density and etch rate associated with an ICP reactor and a high etch selectivity associated with a CCP reactor. Such a method and apparatus would permit relatively deep holes to be etched in the workpiece, with good selectivity, and reduce workpiece's processing time.

This would also broaden the narrow process windows of etch processes. Specifically, the method and the apparatus would permit active control of the density of species generated within a plasma so that the etch selectivity would be decoupled from etch stop depth.

Stated another way, it would be desirable to decouple dissociation of the reactive constituents from ionization of the non-reactive gas components. This would allow both the etch selectivity and etch stop depth to be increased rather than one increasing while the other decreases. A broader process window would also save cost and time on plasma etch processing and make process easier to use.

Thus, what is also needed is a mechanism for controlling the amount of dissociation of reactive gasses without changing the amount of energy applied to generate the plasma.

### SUMMARY OF THE INVENTION

This invention affords the ability to do two things. First, it gives the ability to make dissociation of reactive gasses independent from ionization of dilutant gasses. Second, it gives the ability to control the amount of dissociation of reactive gasses in a new way.

This is accomplished by injecting the reactive gasses at a different location, with respect to the wafer surface, than the dilutant gasses. Specifically, the distance between the respective injection locations for the reactive and dilutant gasses is substantially larger that the distance between the injection location for the reactive gasses and the wafer. This diversity of injection location helps makes dissociation of reactive gasses independent from ionization of dilutant gasses. The ability to adjust the injection point of the gasses further provides the ability to control dissociation in a way that has been unavailable prior to this invention. It provides a way to control the degree of dissociation according to specific process requirements.

The main RF source (inductive or capacitive) provides bias to the wafer or energy to the ions needed for plasma processing while causing only minimum dissociation of the reactive gas into reactive species.

The independence of reactant dissociation from dilutant ionization is emphasized by the addition to the processing chamber of a secondary plasma source at the top of the chamber to ionize the dilutant gas. Since the reactants are farther away from the secondary plasma source, their dissociation by that source is minimal.

A plasma processing system that combines the above characteristics enables processing with a minimum (and, if desired, controllable) degree of dissociation and ionization of the reactive species in the plasma.

According to one aspect of the invention, reactive gasses are injected into the processing chamber at a position between the wafer support pedestal and the structure for injecting dilutant gasses.

According to another aspect of the invention, reactive gasses are injected into the processing chamber at selectable positions between the wafer support pedestal and the structure for injecting dilutant gasses.

According to a further aspect of the invention, a secondary source is located adjacent the location where dilutant gasses are injected so as to provide increased ionization of the dilutant gasses without substantially increasing the amount of dissociation of the reactive gasses.

According to still another aspect of the invention, independence of the degree of dissociation of the reactive gasses from the amount of ionization of the dilutant gasses promotes both high etch rate and high selectivity.

By reducing the spacing between the nozzle and the wafer surface (and also the pump out port), the reactive gasses traverse a distance that is a smaller multiple of the mean free path length. As a result the reactive gas molecules are subjected to only 1 to 2 collisions/dissociations, not the 3 to 4 collisions/dissociations as would occur in prior art systems. This reduces the amount of free radicals produced.

### BRIEF DESCRIPTION OF THE DRAWINGS

FIG. 1 illustrates a sectional view of a plasma processing chamber with process gas injection structure according to a first embodiment of the invention.

FIG. 2 illustrates a sectional view of a plasma processing chamber with process gas injection structure according to a second embodiment of the invention.

FIG. 3 illustrates a sectional view of a plasma processing chamber with process gas injection structure according to a third embodiment of the invention.

FIG. 4 illustrates a sectional view of a plasma processing chamber with process gas injection structure according to a fourth embodiment of the invention.

FIG. 5 illustrates a bottom plan view of the gas distribution structure of FIG. 4.

FIG. 6 illustrates a sectional detail view of a gas nozzle in the gas distribution structure of FIG. 4.

FIG. 7 illustrates a detail bottom plan view of an annular slot gas nozzle according to an alternate embodiment.

FIG. 8 illustrates a sectional view of a plasma processing chamber with process gas injection structure according to a fifth embodiment of the invention.

### DETAILED DESCRIPTION OF EMBODIMENTS OF THE INVENTION

The present invention may be embodied variously as a processing chamber or as a method for processing a wafer.

According to the chamber embodiments, the processing chamber is useful for plasma processing of a semiconductor wafer. The processing chamber includes a vacuum vessel and a wafer pedestal disposed inside the vessel on which a wafer may lie when being processed. The processing chamber also includes a dilutant gas injector assembly and a reactive gas injector assembly, each delivering gas inside the vessel. The reactive gas injector assembly delivers gas substantially closer to the wafer pedestal than the dilutant gas injector assembly. A primary source provides plasma excitation energy to processing gasses inside the vessel.

According to at least one embodiment, the reactive gas injector assembly extends below the dilutant gas injector assembly, towards the wafer pedestal. According to at least one embodiment, a secondary source is included in the chamber and is positioned adjacent the dilutant gas injector assembly. According to at least one embodiment, the position of injection ports of the reactive gas injector assembly is adjustable.

One aspect of a processing chamber embodied according to the present invention is the shape of the gas injection ports. According one alternate embodiment, each of the injection ports is shaped so as to form an annular nozzle. According another alternate embodiment, each of the injection ports is shaped so as to form an annular slot nozzle.

A method to practice the present invention includes a method of processing a semiconductor wafer using plasma. The method includes placing the semiconductor wafer on a wafer pedestal disposed inside a vacuum vessel and injecting process gasses into the vessel. A dilutant gas is injected into the vessel at a first location above the semiconductor wafer. A reactive gas is injected into the vessel at a second location above the semiconductor wafer, the second location being positioned substantially closer to the wafer than the first location. The dilutant and reactive gasses in the vessel are excited with electromagnetic energy from a primary excitation source to provide a plasma. A secondary excitation source is used to excite substantially only the dilutant gasses in the vessel.

As discussed within this application, the term semiconductor is not intended to be limited only to workpieces where the substrate is formed of a semiconductor. The term semiconductor wafer is expressly intended to include workpieces that have semiconductor devices formed on a supporting substrate that is formed from materials other than semiconductor. Examples of such supporting substrates, without limitation, are glass substrates and ceramic substrates used to produce, for example, liquid crystal displays and other products.

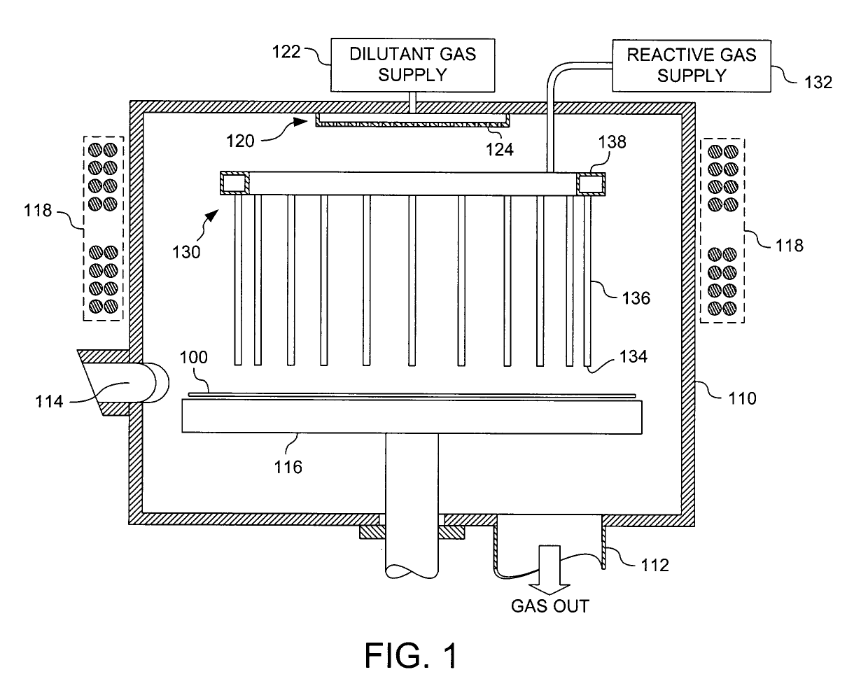

Referring to FIG. 1, a sectional view of a plasma processing chamber with process gas injection structure according to a first embodiment of the invention is illustrated. The chamber 110 maintains a nominal vacuum when pumped out by a vacuum pump (not shown) via the pumping port 112. Semiconductor wafers are transported in and out of the chamber 110 via the slit valve passage 114. When a semiconductor wafer 100 is to be processed, it is placed atop the pedestal 116. Optionally, a bias supply (not shown) applies a bias to the wafer 100 via the pedestal 116 to enhance the plasma processing. A primary source 118 for applying RF energy to the interior of the chamber 110 via inductive coupling is disposed adjacent the chamber 110. The primary source 118 illustrated is simply an example, as its physical configuration (i.e., the number of wiring turns and their relative diameters and positions to one another) may vary greatly, as may its relative placement adjacent the chamber 110. Optionally, the primary source 118 may even be placed inside the chamber.

Introduction of process gasses into the chamber 110 is via a dual distribution arrangement. Dilutant gasses (e.g., argon) are provided from a dilutant gas supply 122 to the interior of the chamber 110 via a dilutant gas injector assembly 120 that has gas injection ports 124. In this illustrated embodiment, the dilutant gas injector assembly 120 has a “shower head” shape, however, other shapes are also suitable. Reactive gasses are provided from a reactive gas supply 132 to the interior of the chamber 110 via a reactive gas injector assembly 130 that has gas injection ports 134 disposed at the end of elongate gas distribution members 136 that extend downward from a manifold 138 toward the semiconductor wafer 100 lying atop the pedestal 116.

The pedestal 116 in the illustrated embodiment is shown as having a fixed height. However, the pedestal 116 may alternatively be embodied as having an adjustable height.

The relative placement of the reactive gas injection ports 134 and the dilutant gas injection ports 124 with respect to the wafer surface provides for independence between dissociation of the reactive gas and ionization of the dilutant gas. The distances between these ports and the wafer surface are best expressed in terms of mean free path length. The mean free path length is the average distance a particle travels in a vacuum before it collides with another particle. As the pressure in the processing chamber increases, the mean free path length becomes shorter; as the pressure decreases it becomes longer.

The reactive gas injection ports 134 are generally placed so that the reactive gas molecules undergo, on average, only about 1 to 2 collisions, each inelastic collision tending to cause a dissociation of the molecule or its constituent into smaller constituents. This distance is between about 1 to 3 mean free path lengths. For many processes, a distance of about 2 mean free path lengths will work satisfactorily. Since mean free path length is pressure dependent, the placement of the reactive gas injection ports 134 is set based on an assumption of the approximate pressure at which the process will be operated.

The dilutant gas injection ports 124 are generally placed so that the dilutant gas molecules undergo, on average, at least 3 collisions, each inelastic collision tending to cause an ionization of the dilutant molecule or its constituents. This distance is about 3 or more mean free path lengths. For many processes, a distance of about 4 mean free path lengths will work satisfactorily. Since mean free path length is pressure dependent, the placement of the dilutant gas injection ports 124 is set based on an assumption of the approximate pressure at which the process will be operated. For example, most etch processes are performed at 10-500 mTorr.

The absolute distance from the ports 124, 134 to the wafer 100 is not so important as the difference between the distances to the wafer from the dilutant gas injection ports 124 and from the reactive gas injection ports 134. It is this diversity of travel distance for the dilutant gas compared with the reactive gas that is effective to provide the advantages of the present invention. So long as this diversity of distance is preserved, the absolute distances may be varied widely depending upon other process conditions or parameters that may need to be accommodated.

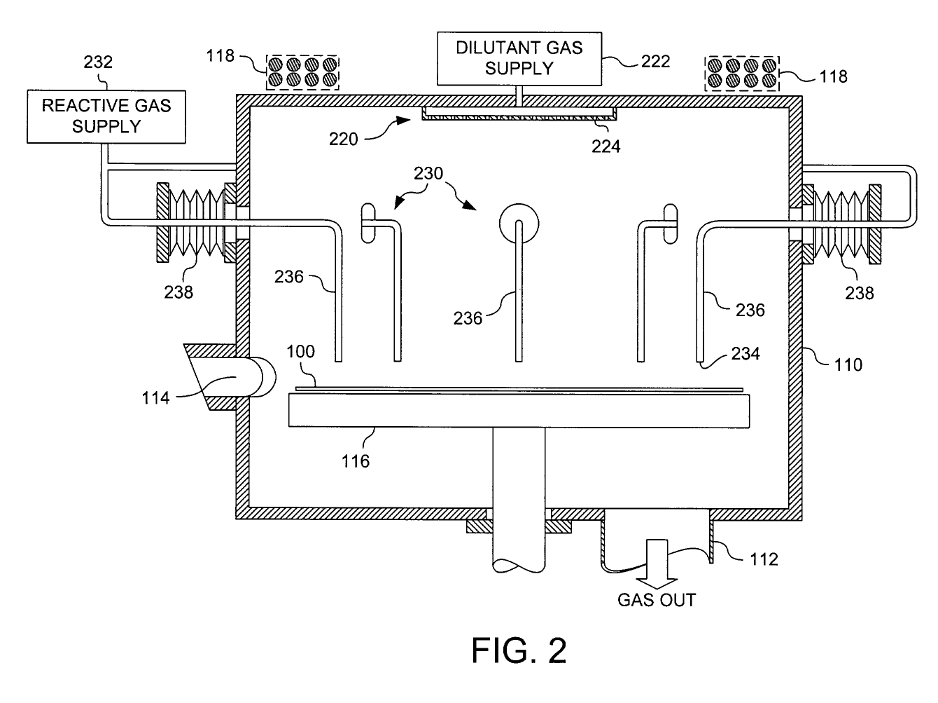

Referring to FIG. 2, a sectional view of a plasma processing chamber with process gas injection structure according to a second embodiment of the invention is illustrated. A semiconductor wafer 100 is disposed inside the chamber 110 for processing. The like numbered structures described above in regard to another embodiment perform like functions in this embodiment.

Introduction of process gasses into the chamber 110 is via a dual distribution arrangement. Dilutant gasses are provided from a dilutant gas supply 222 to the interior of the chamber 110 via a dilutant gas injector assembly 220 that has gas injection ports 224. In this illustrated embodiment, the dilutant gas injector assembly 220 has a “shower head” shape, however, other shapes are also suitable. Reactive gasses are provided from a reactive gas supply 232 to the interior of the chamber 110 via a reactive gas injector assembly 230 that has gas injection ports 234 disposed at the end of elongate gas distribution members 236 that extend downward toward the semiconductor wafer 100 lying atop the pedestal 116. As mentioned above, the height of the pedestal 116 may be alternately embodied as being adjustable. Optionally, a bias supply (not shown) applies a bias to the wafer 100 via the pedestal 116 to enhance the plasma processing.

According to this embodiment, the position of the gas injection ports 234 may be adjusted. The elongate gas distribution members 236 are free to move with respect to the chamber because they are mounted on bellows 238. The elongate gas distribution members 236 may be moved independently or in concert with one another.

The bellows structure 238 shown is but one example of how to implement adjustable gas distribution members 236. Instead of using bellows, the gas distribution members 236 may be alternatively embodied such that they are permitted to slide through o-ring seals. According to another alternative, the gas distribution members 236 are embodied as modular components, thus making them adjusted in the sense that they can be freely disassembled and swapped out for components of a different size when the chamber is opened up between processes. According to yet another alternative embodiment, the gas distribution members 236 are made out of flex hose making them mechanically adjustable.

As with the first embodiment, it is the difference between the distances to the wafer 100 from the dilutant gas injection ports 224 and from the reactive gas injection ports 234 that is effective to bring about the advantages of the present invention.

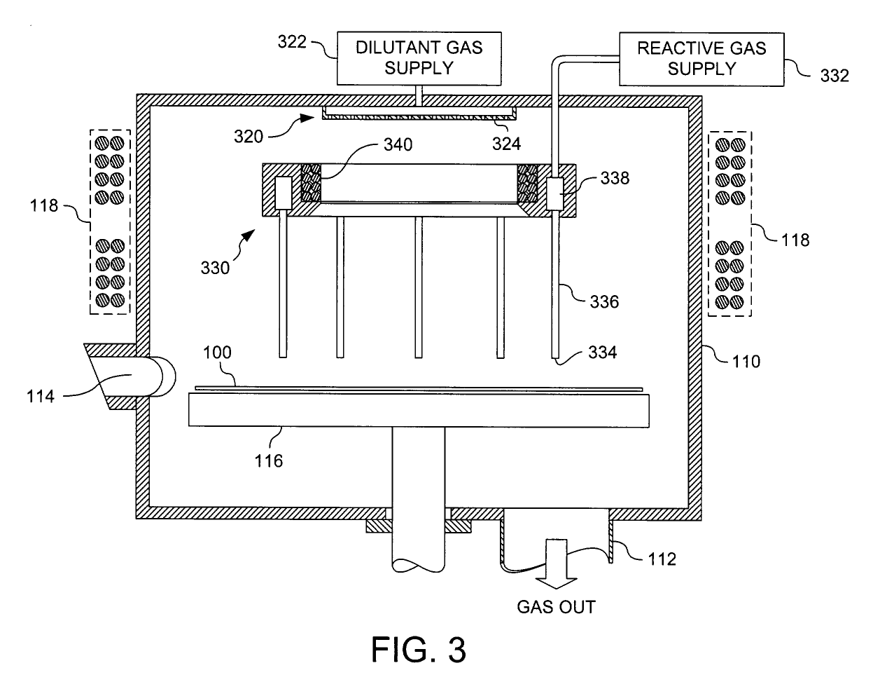

Referring to FIG. 3, a sectional view of a plasma processing chamber with process gas injection structure according to a third embodiment of the invention is illustrated. A semiconductor wafer 100 is disposed inside the chamber 110 for processing. The like numbered structures described above in regard to other embodiments perform like functions in this embodiment.

Introduction of process gasses into the chamber 110 is via a dual distribution arrangement. Dilutant gasses are provided from a dilutant gas supply 322 to the interior of the chamber 110 via a dilutant gas injector assembly 320 that has gas injection ports 324. In this illustrated embodiment, the dilutant gas injector assembly 320 has a “shower head” shape, however, other shapes are also suitable. Reactive gasses are provided by a reactive gas supply 332 to the interior of the chamber 110 via a reactive gas injector assembly 330 that has gas injection ports 334 disposed at the end of elongate gas distribution members 336 that extend downward toward the semiconductor wafer 100 lying atop the pedestal 116. Optionally, a bias supply (not shown) applies a bias to the wafer 100 via the pedestal 116 to enhance the plasma processing.

A secondary source 340 is integrated with the manifold 338 of the reactive gas injector assembly 330 to provide RF excitation energy that is positioned to excite the dilutant gasses exiting the dilutant gas supply 322 without substantially exciting the reactive gasses exiting the reactive gas injection ports 334. This secondary source 340 makes sure that there is still a high density of ionized dilutant gas constituents without substantially promoting further dissociation of the reactive gas molecules. The secondary source 340 may be, for example, an RF powered coil, or an anode countering an RF powered cathode embedded in the pedestal 116. Alternatively, the secondary source 340 may be an RF powered cathode countering a grounded injector assembly 320.

As with the other described embodiments, it is the difference between the distances to the wafer 100 from the dilutant gas injection ports 324 and from the reactive gas injection ports 334 that is effective to bring about the advantages of the present invention. The use of a secondary source 340 emphasizes the effect of this difference of distances.

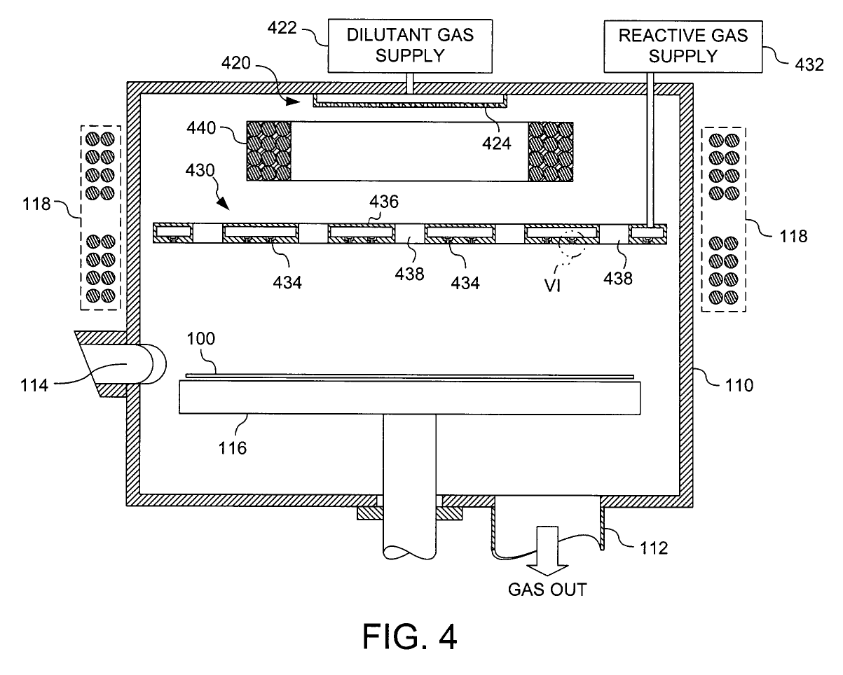

Referring to FIG. 4, a sectional view of a plasma processing chamber with process gas injection structure according to a fourth embodiment of the invention is illustrated. A semiconductor wafer 100 is disposed inside the chamber 110 for processing. The like numbered structures described above in regard to other embodiments perform like functions in this embodiment.

Introduction of process gasses into the chamber 110 is via a dual distribution arrangement. Dilutant gasses are provided from a dilutant gas supply 422 to the interior of the chamber 110 via a dilutant gas injector assembly 420 that has gas injection ports 424. In this illustrated embodiment, the dilutant gas injector assembly 420 has a “shower head” shape, however, other shapes are also suitable. Reactive gasses are provided by a reactive gas supply 432 to the interior of the chamber 110 via a reactive gas injector assembly 430 that has gas injection ports 434 disposed on the underside of a flat gas distribution manifold 436 that extends across the interior of the chamber 110, between the dilutant gas injector assembly 420 and the semiconductor wafer 100 lying atop the pedestal 116. The ionized dilutant gas is permitted to flow down through the flat gas distribution manifold 436 via large holes 438. Optionally, a bias supply (not shown) applies a bias to the wafer 100 via the pedestal 116 to enhance the plasma processing.

A secondary source 440 is adjacent the manifold 436 and disposed between the reactive gas injector assembly 430 and the dilutant gas injector assembly 420 to provide RF excitation energy to excite the dilutant gasses exiting the dilutant gas supply 422 without substantially exciting the reactive gasses exiting the reactive gas injection ports 434. In this example, the flat manifold 436 is conductive and electrically grounded to minimize excitation of the reactive gasses by the secondary source 440. This secondary source 440 makes sure that there is still a high density of ionized dilutant gas constituents without substantially promoting further dissociation of the reactive gas molecules.

As with the other described embodiments, it is the difference between the distances to the wafer 100 from the dilutant gas injection ports 424 and from the reactive gas injection ports 434 that is effective to bring about the advantages of the present invention. The use of a secondary source 440 emphasizes the effect of this difference of distances.

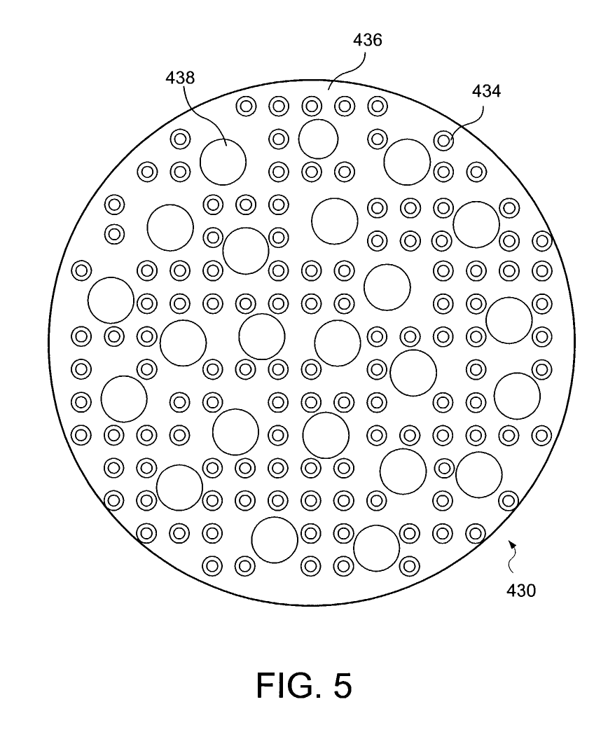

Referring to FIG. 5, a bottom plan view of the reactive gas injector assembly 430 of FIG. 4 is illustrated. Gas injection ports 434 are disposed across the underside of the flat gas distribution manifold 436. A number of large holes 438 are disposed in the manifold 436 to permit flow of ionized dilutant gas down through the manifold. Although the holes 438 and gas injection ports 434 are shown as being round, this is merely an illustrative example and these structures may advantageously be formed according to alternate geometries (e.g., square, triangular, hexagonal, irregular).

The structure according to this embodiment represents a particularly efficient way to ionize a dilutant gas and then mix it with the reactive species thereby enabling reactive ion etch processing. Processing is generally carried out at a low pressure and with a relatively high flow to reduce residence time and prevent reactive species from diffusing upward. In this way, the benefits of both high density plasma (HDP) processing and a highly selective dielectric etch regime are obtained.

As an example, etch processing is carried out with this structure by injecting argon (Ar) gas as a dilutant via the ports 424 of the dilutant gas injector assembly 420 and injecting a mixture of C₄F₆ and O₂ as reactive species via the ports 434 of the reactive gas injector assembly 430. The Ar flows into the portion of the chamber above the reactive gas injector assembly 430, where it is efficiently ionized by the secondary source 440 and then flows downward through the holes 438 where it mixes with the reactive species and impacts the surface of the wafer 100. The holes 438 in the reactive gas injector assembly 430 need to be large enough that the Ar plasma is not quenched in the portion of the chamber below the reactive gas injector assembly 430. However, the holes 438 cannot be made so large that the reactive species are also ionized efficiently.

The distance between the reactive gas injector assembly 430 and the wafer 100 is kept sufficiently small so as to shorten the residence time of the reactive species in the chamber before they are pumped out. The short residence time efficiently controls the degree of dissociation of the reactive species by ensuring that the number of particle collisions is statistically clustered around a low mean.

The secondary source 440 may be embodied as an ICP source, a CCP source, VHF, or MERIE. A toroidal source with a grounded inside surface is good example. Refer to U.S. Pat. No. 6,348,126 for examples of suitable toroidal sources.

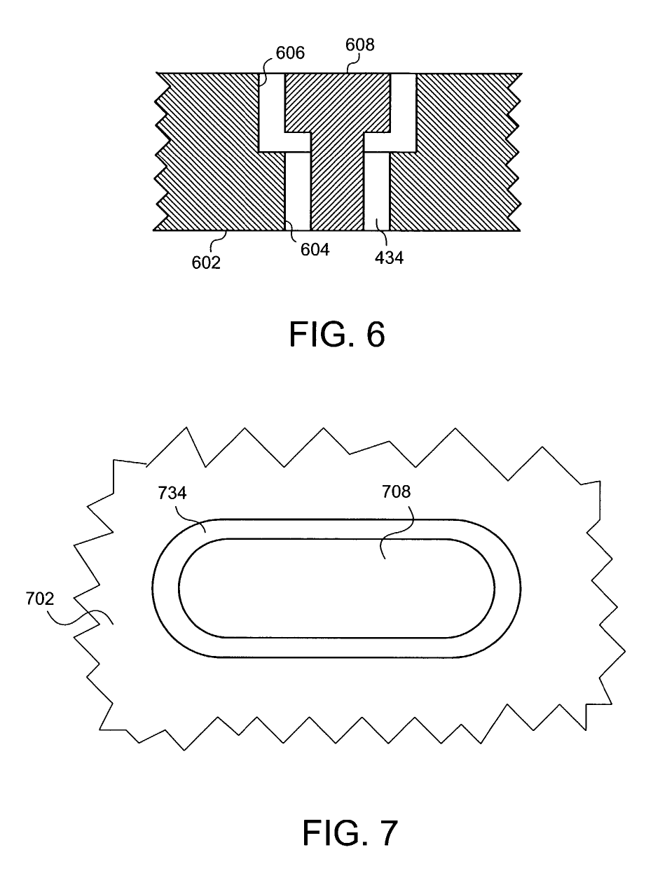

Referring to FIG. 6, a sectional detail view of a gas nozzle in the gas distribution structure of FIG. 4 is illustrated. An annular gas nozzle 434 is formed in the bottom surface 602 of the gas distribution manifold 436. A hole 604 is formed through the bottom surface 602 with a counter bore 606. A central member 608 is disposed centrally in the hole 604, thereby forming the annular gas nozzle 434 between the hole 604 and the central member 608.

Referring to FIG. 7, a detail bottom plan view of an annular slot gas nozzle according to an alternate embodiment is illustrated. Rather than the annular gas nozzle 434 shown in FIG. 6 that has cylindrical symmetry, the gas injection nozzle can be stretched into an elongated format. This annular slot gas nozzle 734 is formed between an elongate central member 708 disposed in a slot with rounded ends formed in the bottom surface 702 of a gas manifold. According to this alternate embodiment, the gas injection nozzles across the bottom of the gas manifold are to be formed in the shape of such annular slots. Forming the gas injection nozzles in this shape has been found to be helpful in suppressing arc formation at the gas distribution assembly.

Each of the various embodiments described above are shown as being implemented with an inductively coupled primary source. However, the invention is not limited to use of and ICP primary source and may be embodied alternatively with a capacitively coupled primary source.

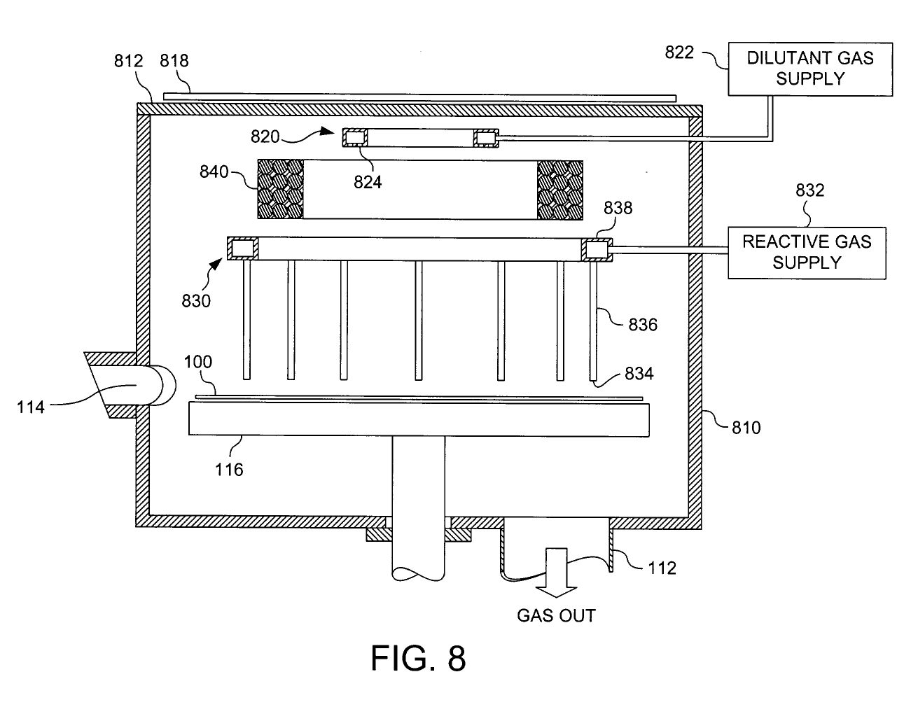

Referring to FIG. 8, a sectional view of a plasma processing chamber with process gas injection structure according to a fifth embodiment of the invention is illustrated. In this case, primary plasma excitation is capacitively coupled. A semiconductor wafer 100 is disposed inside the chamber 810 for processing. The lid 812 of the chamber 810 is formed of a dielectric material, as is generally known in the art when capacitive coupling of RF excitation energy is desired. The like numbered structures described above in regard to other embodiments perform like functions in this embodiment.

A primary source 818 for applying RF energy to the interior of the chamber 810 via capacitive coupling is disposed adjacent the dielectric lid 812 of the chamber 810. The primary source 818 illustrated is simply an example of a capacitive coupling plate, since its physical configuration (i.e., size and shape) may vary greatly, as may its relative placement adjacent the chamber 810. An RF energy source (not shown) is electrically connected to provide RF bias between the primary source 818 and the pedestal 116.

Introduction of process gasses into the chamber 810 is via a dual distribution arrangement. Dilutant gasses (e.g., argon) are provided from a dilutant gas supply 822 to the interior of the chamber 810 via a dilutant gas injector assembly 820 that has gas injection ports 824. In this illustrated embodiment, the dilutant gas injector assembly 820 has a toroidal shape, however, other shapes are also suitable. Reactive gasses are provided from a reactive gas supply 832 to the interior of the chamber 810 via a reactive gas injector assembly 830 that has gas injection ports 834 disposed at the end of elongate gas distribution members 836 that extend downward from a manifold 838 toward the semiconductor wafer 100 lying atop the pedestal 116.

The above description of the various embodiments has been simplified somewhat when stating simply that dilutant gas is injected via dilutant gas injector assemblies and that reactive gas is injected via reactive gas injector assemblies. The description was simplified in this way to help clearly illustrate the basic principle of how dissociation of the reactive gasses is made independent of ionization of the dilutant gasses. In fact, practice of the present invention does not require that a dilutant gas injector assembly inject only pure dilutant gas nor does it require that a reactive gas injector assembly inject only pure reactive gas. According to a generalized mode of practicing the present invention, the reactive gas injector assembly injects a mix of gasses dominated by reactive gas and including a small amount of dilutant gas. Also according to this generalized mode of practice, the dilutant gas injector assembly injects a mix of gasses dominated by dilutant gas and including a small amount of reactive gas.

This mixing of gasses provides a way for modulating the degree to which dissociation is made independent from ionization. Thus, to practice the present invention in a generalize manner, the above descriptions are not meant to limit the present invention to being practiced with only pure dilutant gas being injected by the dilutant gas injector assembly and with only pure reactive gas being injected by the reactive gas injector assembly. Each of these examples will be understood to permit the use of mixtures to the degree desired to modulate the independence affect provided by the present invention. For example, it would be entirely consistent with the above described embodiments of the present invention if a mix of 97% Ar with 3% C₄F₆ is injected from a dilutant gas injector assembly, and a mix of 97% C₄F₆/O₂ and 3% Ar is injected from a reactive gas injector assembly. Such gas mix optimizations do not depart from the scope of the present invention.

The present invention has been described in detail with regard to numerous embodiments thereof, however other versions are possible. For example, the plasma can be formed using a capacitively coupled plasma source rather than the inductively coupled plasma sources illustrated. Therefore, the appended claims should not be limited to the description of the exemplary versions described herein. It will be appreciated that various modifications and improvements may be made to the described embodiments without departing from the scope of the invention.

What is claimed is:

1. A processing chamber for plasma processing of a semiconductor wafer, the processing chamber comprising:
a vacuum vessel;
a wafer pedestal disposed inside the vessel;
a primary excitation source positioned adjacent the vessel to provide plasma excitation energy to processing gasses inside the vessel;
a dilutant gas injector assembly disposed inside the vessel to provide injection of dilutant gas at a first location; and
a secondary excitation source positioned adjacent the dilutant gas injector assembly;
a reactive gas injector assembly disposed inside the vessel to provide injection of reactive gas at a second location;
wherein the distance from the first location to the wafer pedestal is substantially larger than the distance from the second location to the wafer pedestal.

2. The processing chamber of claim 1, wherein the secondary excitation source is adapted to provide plasma excitation energy to substantially only the dilutant gas in the vessel.

3. The processing chamber of claim 1, wherein the difference between the distance from the first location to the wafer pedestal and the distance from the second location to the wafer pedestal provides for independence of the degree of dissociation of reactive gas injected via the reactive gas injector assembly from the amount of ionization of dilutant gas injected via the dilutant gas injector assembly.

4. The processing chamber of claim 1, wherein the distance from the second location to the wafer pedestal is between about 1 and 3 mean free path lengths at a nominal processing pressure.

5. The processing chamber of claim 4, wherein the distance from the second location to the wafer pedestal is about 2 mean free path lengths at a nominal processing pressure.

6. The processing chamber of claim 4, wherein the distance from the first location to the wafer pedestal is at least 4 mean free path lengths at a nominal processing pressure.

7. The processing chamber of claim 1, wherein the wafer pedestal is RF biased.

8. A processing chamber for plasma processing of a semiconductor wafer, the processing chamber comprising:
a vacuum vessel;
a wafer pedestal disposed inside the vessel;
a primary excitation source positioned adjacent the vessel to provide plasma excitation energy to processing gasses inside the vessel;
a dilutant gas injector assembly disposed inside the vessel at a first location; and
a reactive gas injector assembly disposed inside the vessel at a second location, wherein the first location and the second location are positioned, in relationship to the primary source and the wafer pedestal, to provide for establishment of a plasma while minimizing the degree of dissociation of reactive gasses injected via the reactive gas injector assembly.

9. A processing chamber for plasma processing of a semiconductor wafer, the processing chamber comprising:
a vacuum vessel;
a wafer pedestal disposed inside the vessel;
a dilutant gas injector assembly disposed inside the vessel and adapted to inject dilutant gas into the vessel;
a reactive gas injector assembly disposed inside the vessel and adapted to inject reactive gas into the vessel;
a primary excitation source positioned adjacent the vessel and adapted to provide plasma excitation energy to the dilutant gas and to the reactive gas inside the vessel;
a secondary excitation source positioned adjacent the dilutant gas injector assembly and adapted to provide plasma excitation energy to substantially only the dilutant gas in the vessel.

10. A processing chamber for plasma processing of a semiconductor wafer, the processing chamber comprising:
a vacuum vessel;
a wafer pedestal disposed inside the vessel;
a primary source positioned adjacent the vessel to provide plasma excitation energy to processing gasses inside the vessel;
a dilutant gas injector assembly disposed inside the vessel; and
a reactive gas injector assembly disposed inside the vessel, the reactive gas injector assembly being positioned substantially closer to the wafer pedestal than the dilutant gas injector assembly.

11. The processing chamber of claim 10, further comprising:
a secondary source positioned adjacent the dilutant gas injector assembly.

12. The processing chamber of claim 11, wherein the reactive gas injector assembly has plural injection ports.

13. The processing chamber of claim 12, wherein the positioning of the injection ports is adjustable.

14. The processing chamber of claim 13, wherein freedom to adjust the positioning of the injection ports is effected by some portion of the reactive gas injector assembly being formed as a flexible tube.

15. A processing chamber for plasma processing of a semiconductor wafer, the processing chamber comprising:
a vacuum vessel;
a wafer pedestal disposed inside the vessel;
a primary source positioned adjacent the vessel to provide plasma excitation energy to processing gasses inside the vessel;
a dilutant gas injector assembly disposed inside the vessel, above the wafer pedestal; and
a reactive gas injector assembly disposed inside the vessel, the reactive gas injector assembly extending below the dilutant gas injector assembly, towards the wafer pedestal.

16. The processing chamber of claim 15, further comprising:
a secondary source positioned adjacent the dilutant gas injector assembly.

17. The processing chamber of claim 15, wherein the reactive gas injector assembly has plural injection ports.

18. The processing chamber of claim 17, wherein the positioning of the injection ports is adjustable.

19. A processing chamber for plasma processing of a semiconductor wafer, the processing chamber comprising:
a vacuum vessel;
a wafer pedestal disposed inside the vessel;
a primary source positioned adjacent the vessel to provide plasma excitation energy to processing gasses inside the vessel;
a dilutant gas injector assembly disposed inside the vessel, above the wafer pedestal;
a reactive gas injector assembly disposed inside the vessel, below the dilutant gas injector assembly and above the wafer pedestal, and extending substantially across the internal width of the vessel, the reactive gas injector assembly being formed as a substantially flat manifold with plural holes formed therethrough, and having plural injection ports on an underside thereof; and
a secondary source positioned between the dilutant gas injector assembly and the reactive gas injector assembly.

20. A method of processing a semiconductor wafer using plasma, the method comprising:
placing the semiconductor wafer on a wafer pedestal disposed inside a vacuum vessel;
injecting a dilutant gas into the vessel at a first location above the semiconductor wafer;
injecting a reactive gas into the vessel at a second location above the semiconductor wafer, the second location being positioned substantially closer to the wafer than the first location;
exciting the dilutant and reactive gasses in the vessel with electromagnetic energy from a primary excitation source to provide a plasma; and
exciting substantially only the dilutant gasses in the vessel with electromagnetic energy from a secondary excitation source disposed between the first location and the second location.

21. The method of processing a semiconductor wafer using plasma of claim 20, wherein the second location is at a distance from the semiconductor wafer of between about 1 and 3 mean free path lengths at a nominal processing pressure.

22. The method of processing a semiconductor wafer using plasma of claim 21, wherein the second location is at a distance from the semiconductor wafer of about 2 mean free path lengths at a nominal processing pressure.

23. The method of processing a semiconductor wafer using plasma of claim 21, wherein the first location is at a distance from the semiconductor wafer of at least 4 mean free path lengths at a nominal processing pressure.
